(19) United States
(12) Patent Application Publication
(10) Pub. No.: US 2011/0285258 A1
(43) Pub. Date: Nov. 24, 2011

(54) Protection Shell of a Type Suitable for Supporting a Touch Tablet Personal Computer in Multiple Positions

(76) Inventor: Luhui Yuan, Guangdong (CN)

(21) Appl. No.: 12/818,469

(22) Filed: Jun. 18, 2010

(30) Foreign Application Priority Data
May 19, 2010 (CN) 201020197051.5

(51) Int. Cl. H05K 5/02

(52) U.S. Cl. 312/223.2

(57) ABSTRACT

A protection shell of a type suitable for supporting a touch tablet personal computer in multiple positions includes: a protection bottom cover having a recess on a back portion thereof, the recess being provided with holes at an upper portion thereof and with guiding slots at both sides of a middle portion thereof; a supporting cover having a thickness smaller than or equal to the depth of the recess of the protection bottom cover, with protrusions rotatably connected with the holes of the protection bottom cover; and a supporting plate with one end rotatably connected to a middle portion of the supporting cover and the other end having slide blocks received within the guiding slots of the protection bottom cover. The protection shell is portable, and stable and simple in structure, whereby the production efficiency is improved.

### FIELD OF THE INVENTION

The present invention relates to a protection shell of a touch tablet personal computer, and in particular to a protection shell of a type suitable for supporting a touch tablet personal computer in multiple positions that is portable and simple in structure.

### BACKGROUND OF THE INVENTION

With the development in touch screen technology, the touch tablet personal computer (Touch Tablet PC) is increasingly popular, accompanying with which a protection shell for protecting the touch tablet PC is developed.

There are mainly two types of protection shell in the market. The first type is similar to the protection shell for a cell phone. It can protect the touch tablet PC from being scraped, but can not support the touch tablet PC to enable it to stand up so as to make the user comfortable when in use. While the second type has a supporting structure besides the function of the first type, the touch tablet PC can be supported at a suitable angle in order to make the user more comfortable when reading or for other purposes. However, this supporting structure is a rotary disk structure that is complicated in structure, difficult for manufacturing and easy to be damaged. Furthermore, it is inconvenient to carry around because of the protruding of the supporting structure from the protection shell.

### SUMMARY OF THE INVENTION

To solve the problems in the prior art, it is an object of the present invention to provide a protection shell of a type suitable for supporting a touch tablet personal computer in multiple positions that is portable, and stable and simple in structure, whereby the production efficiency is improved.

A protection shell of a type suitable for supporting a touch tablet personal computer in multiple positions comprises a protection bottom cover, a supporting cover and a supporting plate. The protection bottom cover is provided with a recess on its back portion. The recess has holes at its upper portion, for cooperating with the protrusions on the upper end of the supporting cover such that the supporting cover is rotatable with respect to the protection bottom cover. The thickness of the supporting cover is smaller or equal to the depth of the recess on the protection bottom cover, thus the supporting cover can be entirely contained within the recess without being exposed out of the protection bottom cover. The protection shell has a beautiful and simple appearance after the supporting cover is completely contained in the recess and is also convenient to be placed in a briefcase. This is in accordance with the portability property of the touch tablet PC.

The recess is provided guiding slots at both sides of its middle portion. The supporting plate is rotatably connected to the middle portion of the supporting cover at one end and is provided with slide blocks at the other end. The slide blocks are received within the guiding slot. The rotation of the supporting cover is limited by the supporting plate, and a supporting force is thus provided when the supporting cover is opened.

The upper end of the guiding slot is higher than the upper end of the supporting plate after the supporting plate is received within the recess such that the supporting plate can be entirely received within the recess as the supporting cover is received within the recess.

After the supporting plate is completely opened from the recess, the lower end of the guiding slot is lower in horizontal position than the end of the supporting plate that is rotatably connected to the supporting cover. Thus, the supporting plate, the supporting cover and the protection bottom cover form a stable triangular supporting structure.

When the supporting cover is used as the supporting pole for supporting the protection bottom cover, a resistance force is provided by the supporting plate to enable the supporting cover to withstand a downward pressure. With this supporting structure, the touch tablet PC can be supported at an inclined angle larger than 45 degree so as to facilitate it to be used for reading and seeing a movie.

While when the supporting plate is used as the supporting pole for supporting the protection bottom cover, a resistance force can be provided by the supporting cover to enable the supporting plate to withstand a downward pressure. With this supporting structure, the touch tablet PC can be supported at an inclined angle smaller than 45 degree so as to facilitate it to be used for touching and operating the screen of the touch tablet PC. The screen conversion between these two use positions of the touch tablet PC can be realized by the gravity sensing system in the touch tablet PC.

Position limiting protrusions are provided on the lower end of the supporting cover. Correspondingly, the recess is provided with position limiting holes for cooperating with the position limiting protrusions of the supporting cover. Therefore, the supporting cover will be retained in position when being received within the recess such that the supporting cover will not be detached from the protection bottom cover easily.

Preferably, an anti-slide mat is provided at the lower end of the external surface of the supporting cover. Thus, when the supporting plate is used as the supporting pole for supporting the protection bottom cover, the touch tablet PC will not be slid easily.

Preferably, positioning protrusions for the supporting plate are provided on the lower end of the recess to provide a resistance force for the supporting plate such that the supporting plate will not be closed easily. The touch tablet PC is thus protected from losing support.

Furthermore, a protection face cover for cooperating with the front of the protection bottom cover is preferably provided.

### BRIEF DESCRIPTION OF THE DRAWINGS

FIG. 1 is a schematic view of a protection shell according to an embodiment of the present invention;

FIG. 2 is a schematic view of the protection shell viewed from other direction.

Wherein:

1. protection bottom cover; 2. supporting cover; 3. supporting plate; 4. recess; 5. guiding slot; 6. position limiting protrusion; 7. position limiting hole; 8. anti-slide mat; 9. positioning protrusion.

### DETAILED DESCRIPTION OF THE PREFERRED EMBODIMENT

The following description of the preferred embodiments of the invention are disclosed herein, however, it is to be understood that the disclosed embodiments are merely exemplary and are in no way intended to limit the invention.

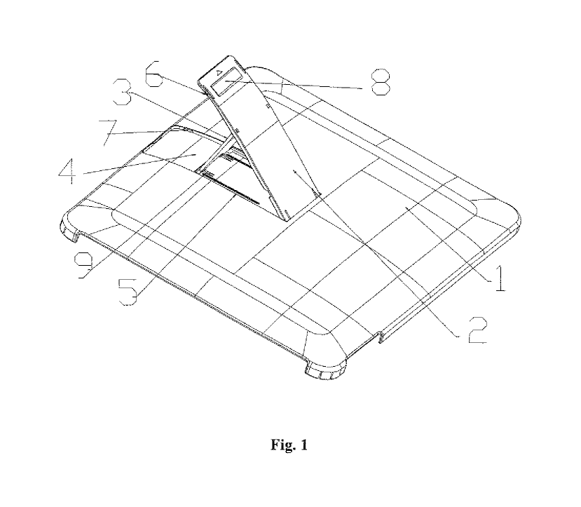

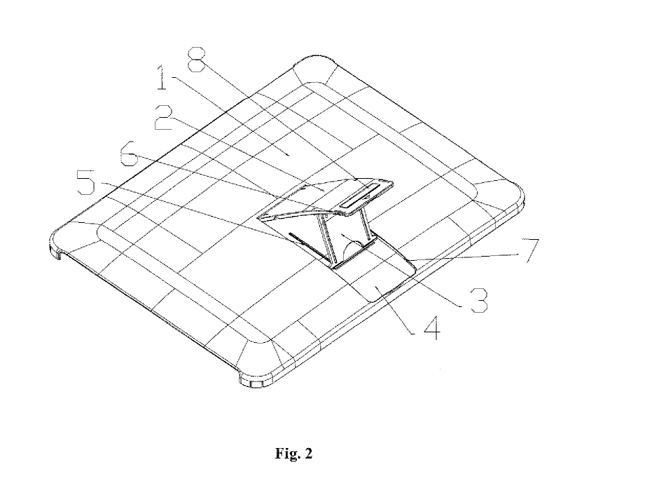

Referring to FIGS. 1 and 2, the protection shell of a type suitable for supporting a touch tablet personal computer in multiple positions comprises a protection bottom cover 1, a supporting cover 2 and a supporting plate 3. The protection bottom cover 1 is provided with a recess 4 on its back portion. The recess 4 has holes at its upper portion, for cooperating with the protrusions on the upper end of the supporting cover 2 such that the supporting cover 2 is rotatable with respect to the protection bottom cover 1. The thickness of the supporting cover 2 is smaller or equal to the depth of the recess 4 on the protection bottom cover 1, thus the supporting cover 2 can be entirely contained within the recess 4 without being exposed out of the protection bottom cover 1. The protection shell has a beautiful and simple appearance after the supporting cover 2 is completely contained in the recess 4 and is also convenient to be placed in a briefcase. This is in accordance with the portability property of the touch tablet PC.

The recess 4 is provided guiding slots 5 at both sides of its middle portion. The supporting plate 3 is rotatably connected to the middle portion of the supporting cover 2 at one end and is provided with slide blocks at the other end. The slide blocks are received within the guiding slot 5. The rotation of the supporting cover 2 is limited by the supporting plate 3, and a supporting force is thus provided when the supporting cover 2 is opened.

The upper end of the guiding slot 5 is higher than the upper end of the supporting plate 3 after the supporting plate 3 is received within the recess 4 such that the supporting plate 3 can be entirely received within the recess 4 as the supporting cover 2 is received within the recess 4.

The lower end of the guiding slot 5 is lower than the end of the supporting plate 3 that is rotatably connected to the supporting cover 2 in horizontal position after the supporting plate 3 is completely opened from the recess 4. Thus, the supporting plate 3, the supporting cover 2 and the protection bottom cover 1 form a stable triangular supporting structure.

When the supporting cover 2 is used as the supporting pole for supporting the protection bottom cover 1, a resistance force is provided by the supporting plate 3 to enable the supporting cover 2 to withstand a downward pressure. With this supporting structure, the touch tablet PC can be supported at an inclined angle larger than 45 degree so as to facilitate it to be used for reading and seeing a movie.

While when the supporting plate 3 is used as the supporting pole for supporting the protection bottom cover 1, a resistance force can be provided by the supporting cover 2 to enable the supporting plate 3 to withstand a downward pressure. With this supporting structure, the touch tablet PC can be supported at an inclined angle smaller than 45 degree so as to facilitate it to be used for touching and operating the screen of the touch tablet PC. The screen conversion between these two use states of the touch tablet PC can be realized by the gravity sensing system in the touch tablet PC.

Position limiting protrusions 6 are provided on the lower end of the supporting cover 2. Correspondingly, the recess 4 is provided with position limiting holes 7 for cooperating with the position limiting protrusions 6 of the supporting cover 2. Therefore, the supporting cover 2 will be retained in position when being received within the recess 4 such that the supporting cover 2 will not be detached from the protection bottom cover 1 easily.

An anti-slide mat 8 is provided at the lower end of the external surface of the supporting cover 2. Thus, when the supporting plate 3 is used as the supporting pole for supporting the protection bottom cover 1, the touch tablet PC will not be slid easily.

Positioning protrusions 9 for the supporting plate are provided on the lower end of the recess 4 to provide a resistance force for the supporting plate 3 such that the supporting plate 3 will not be closed easily. The touch tablet PC is thus protected.

A protection face cover for cooperating with the front of the protection bottom cover 1 is preferably provided.

While the present invention is described in connection with what is presently considered to be the most practical and preferred embodiments, it should be appreciated that the invention is not limited to the disclosed embodiments, and is intended to cover various modifications and equivalent arrangements included within the spirit and scope of the claims. Modifications and variations in the present invention may be made without departing from the novel aspects of the invention as defined in the claims, and this application is limited only by the scope of the claims.

What is claimed is:

1. A protection shell of a type suitable for supporting a touch tablet personal computer in multiple positions, comprising:
a protection bottom cover baying a recess on the back thereof, the recess being provided with holes at an upper portion thereof and with guiding slots at both sides of a middle portion thereof;
a supporting cover having a thickness smaller than or equal to the depth of the recess of the protection bottom cover, with protrusions on an upper portion thereof that are rotatably connected with the holes of the protection bottom cover; and
a supporting plate with one end rotatably connected to a middle portion of the supporting cover and the other end having slide blocks received within the guiding slots of the protection bottom cover, said one end being higher than lower ends of the guiding slots in horizontal position after the supporting plate being completely opened from the recess, and said the other end being lower than upper ends of the guiding slots after the supporting plate being completely received within the recess.

2. The protection shell of claim 1, wherein the supporting cover is provided with position limiting protrusions at lower portions thereof, and the recess is provided with position limiting holes for cooperating with the position limiting protrusions of the supporting cover.

3. The protection shell of claim 1, wherein an anti-slide mat is provided on the external surface of the lower end of the supporting cover.

4. The protection shell of claim 1, wherein positioning protrusions for the supporting plate are provided on the lower end of the recess.

5. The protection shell of claim 1, further comprising a protection face cover for cooperating with the front of the protection bottom cover.
